(19) United States
(12) Patent Application Publication
(10) Pub. No.: US 2026/0194584 A1
(43) Pub. Date: Jul. 9, 2026

(54) Lithium Thionyl Chloride Battery Depassivation During Usage and Storage Using a Coulomb Counter Circuit

(71) Applicant: Aclara Technologies LLC, St. Louis, MO (US)

(72) Inventors: Randy John Williams, Cedar Hills, UT (US); Douglas J. Batey, Wadsworth, OH (US); Steven E. Wilder, West Salem, OH (US)

(21) Appl. No.: 19/439,901

(22) Filed: Jan. 5, 2026

Related U.S. Application Data
(60) Provisional application No. 63/742,536, filed on Jan. 7, 2025.

(51) Int. Cl. G01R 31/3835; H01M 10/42; H02J 1/08

(52) U.S. Cl. CPC G01R 31/3835; H01M 10/4285; H02J 1/084

(57) ABSTRACT

A depassivation apparatus includes a voltage monitor and control circuit electrically connected to the cathode of the battery via an isolation switch circuit and an input stabilization circuit. The battery voltage is provided as an input to a voltage monitor and control unit which is connected on its output to a grounded capacitor circuit. In response to the voltage of the capacitor circuit falling to predetermined recharge threshold voltage, the voltage monitor and control circuit controls a constant current source that is turned on to charge the capacitor circuit. Once the capacitor circuit is charged up, the constant current source is turned off. The on/off charging of the capacitor circuit drawn from the battery eliminates the depassivation build up on the battery terminals.

### CROSS-REFERENCE TO RELATED APPLICATIONS

The present application claims priority from, and incorporates herein by reference in its entirety, U.S. provisional patent application 63/742,536 filed Jan. 7, 2025.

### FIELD

The present disclosure relates to an apparatus and method of battery depassivation. More particularly, the present invention related to an apparatus and method for battery depassivation and testing under load to ensure battery operability for an intended use.

### BACKGROUND

Storage of Lithium Thionyl Chloride (LTC) batteries presents an issue due to battery passivation. Passivation is a chemical process that creates a protective layer on a material, for example, on the anodes and cathodes of a battery cells. The buildup of a passivation layer tends to disrupt current flow from the battery. From an electrical perspective, a passivation layer essentially looks like a large series resistance on the cell. This results in a voltage drop when current is drawn from the battery, making the battery appear to have a lower voltage than its actual voltage.

Passivation occurs over time, beginning as soon as a charged battery ceases to deliver current. The rate of passivation is influenced by its environment. For example, storage at higher temperatures accelerates the passivation process. Generally, high levels of current can remove or reduce the passivation from the battery cell. However, after long periods of storage some of the passivation layer cannot be removed, permanently altering the ability of the battery to provide the needed current in a circuit.

The buildup of a passivation layer essentially shortens the expected lifetime of a battery. Passivation can also potentially cause errors in the circuitry that depends on the battery voltage to remain stable. Batteries with a passivation layer that cannot be removed must be discarded. It can take considerable effort to determine which batteries, if any, have passivation damage to the point where they are no longer suitable for use.

### SUMMARY

Various embodiments of the present disclosure can overcome the afore-mentioned disadvantages and other drawbacks associated with the buildup of passivation layers on LTC batteries, and offers new advantages as well. For example, various embodiments disclosed herein send a constant current to a capacitor circuit in response to the capacitor circuit falling below a predetermined threshold. Once the capacitor circuit is charge back up to its nominal voltage, the constant current is turned off, allowing the capacitor circuit to again fall in voltage to the predetermined threshold. The ON-OFF action of the current source is powered by the battery, resulting in the battery producing a steam of low current pulses. The stream of from the battery low current pulses are at an amperage small enough to cause negligible battery drain, but of sufficient amperage to prevent battery depassivation.

According to various embodiments of the present disclosure there is provided an apparatus and method of automated D-cell Lithium Thionyl Chloride (LTC) battery depassivation that includes removable for detachably connecting to the battery terminals, a voltage monitor and control circuit that includes a monitor input terminal and a monitor output terminal characterized by a monitor_output_voltage. The monitor input terminal is electrically connected to a first one of the removable electrodes. The depassivation apparatus also includes a constant current source configured to receive current from the battery and controllably provide a constant current to the monitor output terminal, and a pair of supercapacitors in series to ground and electrically connected to the monitor output terminal. In response to detecting the monitor_output_voltage to be less than a predetermined recharge threshold voltage, the voltage monitor and control circuit controls the constant current source to turn to an ON state to provide the constant current to the capacitor via the monitor output terminal.

In some forms of the depassivation apparatus, in response to detecting the monitor_output_voltage to be equal or greater than a nominal voltage, the voltage monitor and control circuit controls the constant current source to turn to an OFF state, ceasing the constant current to the capacitor. In some forms the depassivation apparatus the constant current is 75+/−25 mA.

In some forms of the depassivation apparatus, with the constant current source in an OFF state the monitor output terminal is blocked from delivering any current from the battery to a load connected to the monitor output terminal.

In some forms of the depassivation apparatus the constant current source is configured as part of the voltage monitor and control circuit.

In some forms, the depassivation apparatus includes an input stabilization circuit that has at least one capacitor. In some forms the monitor input terminal is electrically connected to the first electrode via the input stabilization circuit.

In some forms of the depassivation apparatus the capacitor is a first supercapacitor. In some forms the depassivation apparatus includes a second supercapacitor electrically connected between the capacitor terminal of the first supercapacitor and the second battery terminal.

In some forms, the depassivation apparatus includes capacitor balancing circuitry connected to the capacitor terminal of the first supercapacitor. In some forms, the depassivation apparatus includes an isolation switch circuit including an isolation input terminal electrically connected to the first battery terminal, and an isolation output terminal.

In some forms of the depassivation apparatus the battery is a voltage source to the voltage monitor and control circuit, powering logic circuits within the voltage monitor and control circuit. In some forms of the depassivation apparatus a voltage at the monitor output terminal is less than a voltage at the monitor input terminal by a first value within the range of 150+/−50 mV, and the predetermined recharge threshold voltage is a second value within the range of 65+/−30 mV.

In some forms of the depassivation apparatus the voltage monitor and control circuit is a coulomb counter integrated circuit.

### BRIEF DESCRIPTION OF THE DRAWINGS

Various aspects and advantageous features of the present disclosure will become more apparent to those of ordinary skill when described in the detailed description of preferred embodiments and reference to the accompany drawing wherein:

FIG. 1 depicts a block diagram of an automated D-cell Lithium Thionyl Chloride (LTC) battery depassivation apparatus according to various embodiments disclosed herein.

FIG. 2 depicts a circuit diagram of an automated D-cell LTC battery depassivation apparatus according to various embodiments disclosed herein.

FIG. 3 depicts an apparatus for measuring, monitoring and communicating electrical parameters on a utility pole which utilizes the automated D-cell LTC battery depassivation apparatus according to various embodiments disclosed herein.

### DETAILED DESCRIPTIONS

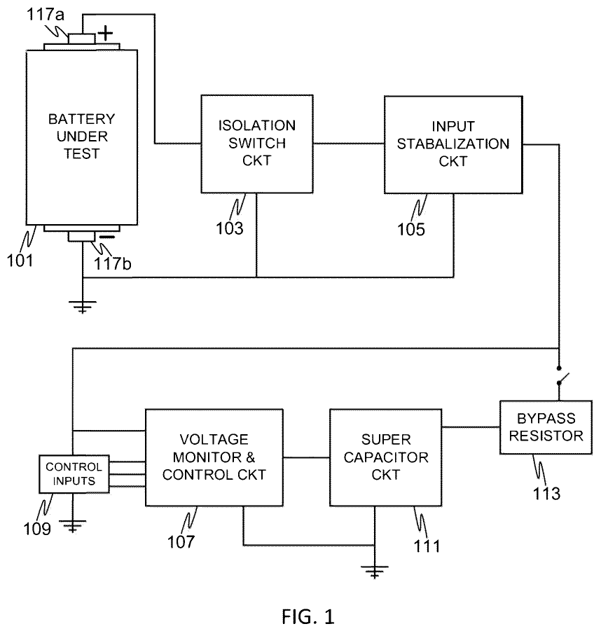

FIG. 1 depicts a block diagram of an automated D-cell LTC battery depassivation apparatus 100 according to various embodiments disclosed herein. The battery depassivation apparatus 100 includes removable electrodes 117a-b for connecting to a battery 101, an isolation switch circuit 103, an input stabilization circuit 105, a voltage monitor and control unit 107, control inputs circuitry 109, supercapacitor circuitry 111 and a bypass resistor 113. The various components of the battery testing apparatus 100 may be interconnected in the manner depicted in FIG. 1.

The removable electrodes 117a-b are configured to be removably attached to the terminals of the battery 101 that is under test. The battery 101 has a voltage of V_{BAT}. If battery 101 is an LTC battery, then V_{BAT} equals approximately 3.6 volts. The removable electrodes 117a-b are constructed from a conductive—i.e., metal—material, and may take the form of clips that attach to the terminals, spring loaded electrodes, threaded connectors, or other such mechanical connector configurations for making electrical contact as are known to those of ordinary skill in the art. As shown in FIG. 1 removable electrode 117a attaches to the cathode (+ terminal) of the battery 101, and removable electrode 117b attaches to the anode (− terminal) of battery 101.

The isolation switch circuit 103 is controllable to electrically connect and disconnect the positive battery terminal (via removable electrode 117a) to/from the rest of the circuitry in the battery depassivation apparatus 100. This is useful, for example, during manufacturing testing to remove the battery 101 from powering the rest of the circuitry so an external supply can be connected downstream from the isolation switch circuit 103. The isolation switch circuit 103 may be implemented with P-channel MOSFET transistor, another type of field effect transistor (FET), a general purpose transistor, or it may be implemented with other switching components such as a relay, a solenoid switch, or other type of wired or wireless remote controllable switches or switching circuitry known to those of ordinary skill in the art.

Input stabilization circuitry 105 is electrically connected to the output of isolation switch circuit 103. The input stabilization circuitry 105 helps to stabilize the input from high frequency noise and reduce harmonics and spurious high frequency spikes to the rest of the circuitry in the battery depassivation apparatus 100. The input stabilization circuitry 105 also provides a bit of delay during the switching process. The input stabilization circuitry 105 typically includes one or more capacitors connected between the output of isolation switch circuit 103 and ground.

The output of isolation switch circuit 103 is electrically connected to the input of voltage monitor and control unit 107. With the isolation switch circuit 103 open (conducting) the voltage V_{BAT_IN} at the input of voltage monitor and control unit 107 is approximately equal to V_{BAT}, the voltage of battery 101 (V_{BAT} may also be referred to as battery voltage). There may be a very small voltage drop across isolation switch circuit 103, but for the purposes of these explanations we will consider V_{BAT_IN} to be equal to V_{BAT}. The BAT_OUT output of voltage monitor and control unit 107 is approximately 150 mV lower than its BAT_IN input due to the voltage drop across internal circuitry of voltage monitor and control unit 107. Thus, due to its internal voltage drop, the V_{BAT_OUT} nominal value of the voltage monitor and control unit 107 output at BAT_OUT is approximately 150 mV less than the voltage of BAT_IN which is at the battery 101 voltage, V_{BAT}. In practice, the 150 mV input to output (BAT_IN-to-BAT_OUT) voltage differential may vary somewhat depending upon the configuration and parameters of voltage monitor and control unit 107. In various embodiments the input to output (BAT_IN-to-BAT_OUT) voltage differential is value within the range of 150+/−50 mV. In other implementations the BAT_IN-to-BAT_OUT voltage differential is value within the range of 100+/−50 mV.

Battery 101 serves as a voltage source to power the internal logic of the voltage monitor and control unit 107. The voltage monitor and control unit 107 is powered by battery 101 to monitor the voltage V_{BAT_OUT} on its BAT_OUT output. If the V_{BAT_OUT} voltage falls below a predetermined recharge threshold, the voltage monitor and control unit 107 turns to an ON state, providing a constant current source out of BAT_OUT until the V_{BAT_OUT} voltage rises to its nominal level V_{BAT_OUT} (which equals V_{BAT}).

The BAT_OUT output of voltage monitor and control unit 107 is electrically connected to supercapacitor circuit 111. The voltage monitor and control unit 107 monitors the voltage at the connection of its BAT_OUT output to supercapacitor circuit 111. In response to the voltage of supercapacitor circuit 111 (i.e., the voltage at the BAT_OUT output of voltage monitor and control unit 107) falling below the predetermined recharge threshold, the voltage monitor and control unit 107 responds by turning to an ON state, which results in a constant current source being supplied to the supercapacitor circuit 111 until it is charged back up to its nominal voltage V_{BAT_OUT}. This process repeats continuously, producing a stream of current pulses from the voltage monitor and control unit 107 to the supercapacitor circuit 111.

The current pulses of the voltage monitor and control unit 107 allow batteries such as battery 101 to be installed in an electrical device without running the risk of passivation deteriorating the functionality of the device. The current amplitude of the pulses that happen during storage are high enough to mitigate the passivation, but the average current is still low enough that the product lifetime is not adversely affected. The voltage monitor and control unit 107—which may be implemented as a coulomb counter—has is a very low energy circuit that requires less than 300 nA of additional current to run. This makes the voltage monitor and control unit 107 (e.g., coulomb counter) virtually irrelevant to the life of the product while providing the ability to hold off passivation. As an added benefit, the coulomb counter is able to determine the amount of energy that is consumed from the battery at any given time. This count can be read by the assembly or the data aggregator to determine if there is a fault condition in the field. The data aggregator can also communicate this information to internal system monitoring software or to external software resources, where required.

The predetermined recharge threshold, as measured at the BAT_OUT output is set to be slightly less than V_{BAT_OUT}. For example, in one implementation the predetermined recharge threshold is set to be 50 mV less than the nominal value of V_{BAT_OUT}. So once the voltage of supercapacitor circuit 111 falls to 50 mV less than the nominal value of V_{BAT_OUT} the voltage monitor and control unit 107 turns ON to supply a constant current from battery 101 to the supercapacitor circuit 111 until it is charged back up to its nominal V_{BAT_OUT} voltage. The ON-OFF operation of voltage monitor and control unit 107 can be thought of as sending a stream of current pulses to the supercapacitor circuit 111. The stream of current pulses keeps the supercapacitor circuit 111 charged to within 50 mV of the nominal value of V_{BAT_OUT} and prevents battery passivation on the terminals of battery 101. In various implementations the predetermined recharge threshold may be set to be larger or smaller than 150 mV, which affects the frequency of sending the voltage pulses. For example, in various implementations the predetermined recharge threshold voltage may be set at any voltage of from 1 mV to 1.5 volts. In various embodiments the predetermined recharge threshold is set to be a value within the range of 65+/−30 mV.

A bypass resistor 113 may be provided to bypass the voltage monitor and control unit 107. If installed, the bypass resistor 113 is connected between the input BAT_IN of voltage monitor and control unit 107 to its BAT_OUT output. The bypass resistor 113 removes the functionality of the voltage monitor and control unit 107 from battery depassivation apparatus 100. In normal operation, however, the bypass resistor 113 is not installed, or is left open as shown in FIG. 1.

The battery 101 powers the battery depassivation apparatus 100, including the voltage monitor and control unit 107 which sends a stream of current pulses to supercapacitor circuit 111. The stream of periodic current pulses prevents battery depassivation on the terminals of battery 101. The pulse widths and pulse frequency are designed to be sufficient to prevent battery depassivation, but without significantly draining the battery 101.

The pulse widths, pulse frequency and pulse voltage can be controlled by selecting predetermined recharge threshold, the capacitance of supercapacitor circuit 111 and the various inputs to the voltage monitor and control unit 107. The control inputs circuitry 109 control the amplitude of the current source pulses from the voltage monitor and control unit 107. The control inputs circuitry 109 can be altered to program the voltage monitor and control unit 107 for a desired output. For example, the pulse current can be controlled by changing the control inputs circuitry 109. A typical value of the current from the current source is 75 mA. However, in various implementations the battery depassivation apparatus 100 may be controlled by the control inputs circuitry 109 to deliver as much as 100 mA of current or as little as 5 mA. In various embodiments the constant current is a value from within the range of 75+/−25 mA.

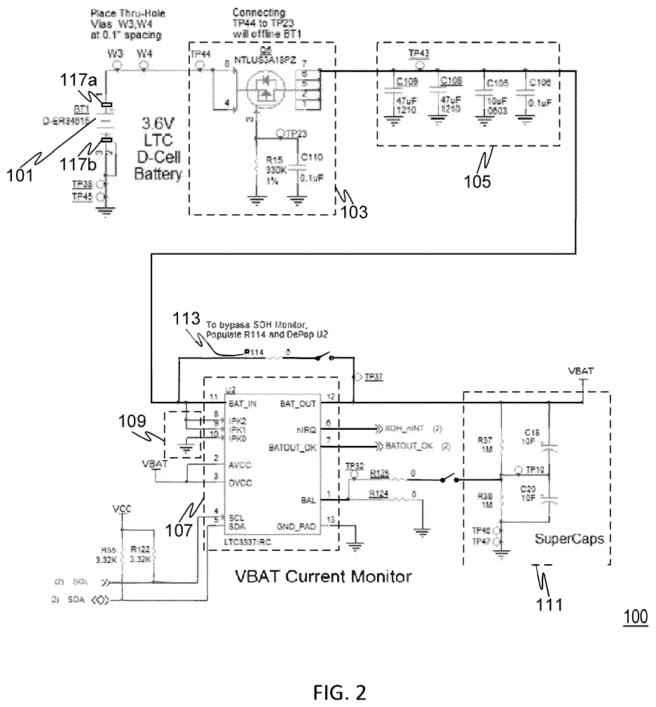

FIG. 2 depicts a circuit diagram of an automated D-cell Lithium Thionyl Chloride (LTC) battery depassivation apparatus 100 according to various embodiments disclosed herein. The battery depassivation apparatus 100 includes removable electrodes 117a-b for connecting to a battery 101, circuitry of an isolation switch 103, circuitry of an input stabilization circuit 105, circuitry of a voltage monitor and control unit 107, circuitry of for control inputs 109, circuitry of a supercapacitor 111 and a bypass resistor 113. The various components and circuitry of the battery testing apparatus 100 may be interconnected in the manner displayed in FIG. 2.

The removable electrodes 117a-b are configured to be removably attached to the terminals of the battery 101 that is under test. The removable electrode 117a attaches to the cathode (+ terminal) of the battery 101, and removable electrode 117b attaches to the anode (− terminal) of battery 101 which is typically grounded.

The isolation switch circuit 103 is controllable to electrically connect and disconnect the positive battery terminal (via removable electrode 117a) to/from the rest of the circuitry in the battery depassivation apparatus 100. The isolation switch circuit 103 may be implemented as a P-channel MOSFET transistor with its source connected to the battery 101 cathode via removable electrode 117a, its drain connected to the input stabilization circuitry 105, and its gate connected to ground via a resistor R15 in parallel with a capacitor C110. In the implementation depicted in FIG. 2 the resistor R15 is a 330 kOhm resistor and the capacitor C110 is 0.1 uFarad. Alternatively, the isolation switch circuit 103 may be implemented with another type of field effect transistor (FET), or with components such as a general purpose transistor, a relay, a solenoid switch, or any type of wired or wireless remote controllable switch or switching circuitry known to those of ordinary skill in the art.

The output of isolation switch circuit 103 is electrically connected to input stabilization circuitry 105. As depicted in FIG. 2 the input stabilization circuitry 105 is implemented with four capacitors electrically connected in parallel between the output of isolation switch circuit 103 and ground. In the depicted implementation the four capacitors are C109, a 47 uF capacitor; C108, a 47 uF capacitor; C105, a 10 uF capacitor and C106, a 0.1 uF capacitor. In other implementations a single capacitor may be used, or a combination of other capacitor values. The output of isolation switch circuit 103 and input stabilization circuitry 105 is electrically connected to the input of voltage monitor and control unit 107.

The voltage monitor and control unit 107 may be implemented using a coulomb counter IC such as the LTC3337 made by Analog Devices. For the depicted implementation using an LTC3337 IC, the voltage monitor and control unit 107 will be called a coulomb counter 107. (The LTC3337 component spec and data-sheet published by Analog Devices, Inc. on Apr. 22, 2021 is hereby incorporated by reference in its entirety.) The BAT_IN input of coulomb counter 107 is connected to the battery 101 cathode via removable electrode 117a, the isolation switch circuitry 103, and input stabilization circuitry 105. Thus, the voltage at the BAT_IN input (which may be called V_{BAT_IN}) is held at substantially the same as the voltage of battery 101, so long as the isolation switch circuit 103 is controlled to provide a short circuit to removable terminal 117a affixed to the cathode of battery 101. The voltage V_{BAT_IN} is the same as the battery voltage (V_{BAT}) less a small voltage drop across isolation switch circuitry 103 which is considered negligible for the purpose of this description. Hence, V_{BAT_IN}=V_{BAT}. The coulomb counter 107 is configured with a constant current source. In an ON state, the constant current source delivers current to the BAT_OUT output terminal of coulomb counter 107. In an OFF state the constant current source delivers no current, and blocks the BAT_IN input of coulomb counter 107 from the BAT_OUT output so nothing on the load side (BAT_OUT) can pull current from battery 101.

The nominal voltage on BAT_OUT output of coulomb counter 107 (in the ON state) is V_{BAT_OUT}. With the coulomb counter 107 being controlled to pass the input voltage V_{BAT_IN} at BAT_IN to its output, the BAT_OUT output will have a voltage V_{BAT_OUT} that is approximately 150 mV less than V_{BAT_IN} due to the voltage drop across internal circuitry of coulomb counter 107 (e.g., due to internal op-amp circuitry). Thus, due to its internal voltage drop, the V_{BAT_OUT} nominal value of coulomb counter 107 output at BAT_OUT is approximately 150 mV less than V_{BAT_IN} at the BAT_IN input of the coulomb counter 107.

The BAT_OUT output terminal of coulomb counter 107 is connected to supercapacitor circuit 111. The coulomb counter 107 monitors the voltage at its output terminal, that is, at the connection of its BAT_OUT output which is connected to supercapacitor circuit 111. If the voltage of supercapacitor circuit 111 (i.e., the voltage at the BAT_OUT output of coulomb counter 107) falls below a predetermined recharge threshold, the coulomb counter 107 responds by connecting a constant current source to the BAT_OUT output which is connected to the supercapacitor circuit 111. The constant current source remains connected to the coulomb counter 107's BAT_OUT output terminal until it detects the voltage at BAT_OUT to have risen to the nominal V_{BAT_OUT} voltage, thus indicating the supercapacitor circuit 111 is recharged to its V_{BAT_OUT} nominal voltage value.

Supercapacitors tend to have much higher energy storage capabilities than conventional electrolytic capacitors—typically from 10 to 100 times more energy storage per unit volume or mass than conventional electrolytic capacitors. Moreover, super-capacitors can be designed to have much larger capacitance values than conventional electrolytic capacitors, but also tend to have lower voltage limits. Supercapacitors C18 and C20 can be purchased from any number of vendors so long as the parameters are suitable for supercapacitor circuit 111. For example, part number BCAP0010 P270 S12 is a 10 F supercapacitor made by Maxwell Technologies, and part number SCCT20E106SRB is a 10 F supercapacitor made by Kyocera AVX. Due to the lower voltage limits, two 10 F supercapacitors C18 and C20 are used in series in supercapacitor circuit 111. The various embodiments include two types of capacitor balancing circuitry. First, to avoid a current imbalance, and yet prevent undue current drain, a relatively large resistor can be wired in parallel with each of the two supercapacitors C18 and C20. As shown in FIG. 2 the 1 Mohm resistor R37 is in parallel with supercapacitor C18, and 1 Mohm resistor R38 is in parallel with supercapacitor C20. As an alternative to using a large resistor wired in parallel with each supercapacitor, current imbalances can be avoided through use of the BAL output from coulomb counter 107. This is done by electrically connecting the BAL output to the junction between supercapacitors C18 and C20.

The predetermined recharge threshold at which the constant current source turns on is set to be a voltage of slightly less than the nominal V_{BAT_OUT} voltage. For example, in one implementation the predetermined recharge threshold is set to be 50 mV less than V_{BAT_OUT} nominal voltage value. In response to the coulomb counter 107 detecting the voltage of supercapacitor circuit 111 falling to 50 mV less than V_{BAT_OUT} a constant current source is electrically connected to the supercapacitor circuit 111 via the BAT_OUT output terminal of coulomb counter 107. The constant current source remains connected until the supercapacitor circuit 111 is recharged to the V_{BAT_OUT} nominal voltage value. This results in a current pulse each time the voltage of supercapacitor circuit 111 falls down to the predetermined recharge threshold. By periodically sending these current pulses on its output, the coulomb counter 107 keeps the supercapacitor circuit 111 charged to within 50 mV of the V_{BAT_OUT} nominal value. In various implementations the predetermined recharge threshold may be set to be larger or smaller than 50 mV below V_{BAT_OUT}, which affects the frequency of sending the voltage pulses. For example, in one implementation the predetermined recharge threshold is set to a particular voltage value that falls within the range of 75+/−50 mV below V_{BAT_OUT}. In other various implementations the predetermined recharge threshold voltage may be set at any given voltage of from 1 mV to 1.5 volts below V_{BAT_OUT}. Setting the predetermined recharge threshold voltage closer to the nominal V_{BAT_OUT} voltage results in a higher frequency of shorter current pulses. Setting the predetermined recharge threshold voltage further below V_{BAT_OUT} results in fewer current pulses of longer duration.

A bypass resistor 113 may be provided to bypass the coulomb counter 107. If installed, the bypass resistor 113 is connected between the input of coulomb counter 107 to its output. The bypass resistor 113 removes the functionality of the coulomb counter 107 from battery depassivation apparatus 100. The bypass resistor 113 is a 0 ohm resistor, effectively providing a short from the terminal connected to the BAT_IN input to the terminal connected to the BAT_OUT output. In normal operation, however, the bypass resistor 113 is not installed, or is left open as discussed above and shown in FIG. 1.

The battery 101 powers the battery depassivation apparatus 100, including the coulomb counter 107 which turns ON and OFF to send a stream of current pulses at the nominal V_{BAT_OUT} voltage to supercapacitor circuit 111. The stream of current pulses prevents battery depassivation on the terminals of battery 101. The pulse widths and pulse frequency—which are determined by the selection of the predetermined recharge threshold voltage—are designed to be sufficient to prevent battery depassivation, but without significantly draining the battery 101.

The pulse widths, pulse frequency and pulse voltage can be controlled by selecting predetermined recharge threshold, the capacitance of supercapacitors C18 and C20 in supercapacitor circuit 111, and the IPK0, IPK1 and IPK2 inputs to the coulomb counter 107. The control inputs circuitry 109 serve as inputs to IPK0, IPK1 and IPK2 to control the amplitude of the constant current source from the coulomb counter 107. The control inputs circuitry 109 can be altered to program the constant current source for a desired output. For example, the pulse current can be controlled by changing the control inputs circuitry 109. A typical value of the current from the current source is 75 mA. However, in various implementations the battery depassivation apparatus 100 may be controlled by the control inputs circuitry 109 to deliver as much as 100 mA of current or as little as 5 mA. In various embodiments the constant current is a value from within the range of 75+/−25 mA.

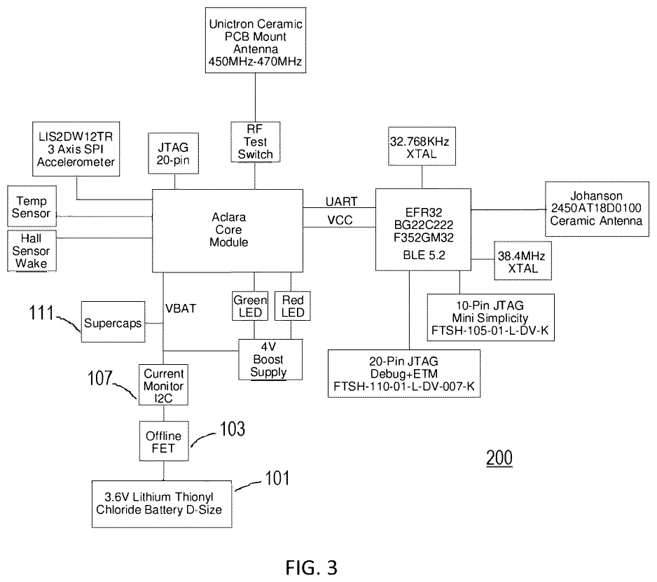

FIG. 3 depicts a monitoring apparatus 200 for measuring, monitoring and communicating electrical parameters on a utility pole which utilizes the automated D-cell LTC battery depassivation apparatus according to various embodiments disclosed herein. The monitoring apparatus 200 is affixed to a utility pole, and is powered by battery 101. The battery 101 has a D-cell LTC battery depassivation apparatus 100 attached to it to prevent battery passivation which occurs over time. This extends the life of battery 101 which is in a location—the top of an electrical utility pole—that is difficult to access to change a battery. The monitoring apparatus 200 depicted in FIG. 3 includes isolation switch circuit 103, voltage monitor and control unit 107 and capacitor circuitry 111 and other associated circuitry of the battery depassivation apparatus 100.

One of ordinary skill will appreciate that the exact dimensions and materials are not critical to the disclosure and all suitable variations should be deemed to be within the scope of the disclosure if deemed suitable for carrying out the objects of the disclosure.

One of ordinary skill in the art will also readily appreciate that it is well within the ability of the ordinarily skilled artisan to modify one or more of the constituent parts for carrying out the various embodiments of the disclosure. Once armed with the present specification, routine experimentation is all that is needed to determine adjustments and modifications that will carry out the present disclosure.

For the sake of brevity, the word “connected” has sometimes been used in this disclosure to mean “electrically connected”. The phrase “electrically connected” is used in the descriptions of the various embodiments. Two components that are “electrically connected” either have their leads fastened together (e.g., soldered together) or are connected by—or via—more conductive components. An LED connected to a 5.0 volt DC power supply via a resistor means that the resistor is in series between the LED and the 5.0 volt DC power supply so that a conductive path is established from the LED through the resistor to the 5.0 volt DC power supply. Also, two components may be connected via a third component even if the path only passes through terminal of the third component. For example, a component may be electrically connected another component (e.g., a power supply) via a third component (e.g., a capacitor) even if the connectivity path only passes through the terminal of the third component (as opposed to passing through the third component as is often done with resistors). Capacitors are often configured this way with the other lead tied to ground in order to reduce spurious signals.

The phrase “detachably connected” is used in the descriptions of the various embodiments. Two components are “detachably connected” if they can be separated and reattached without damaging the two components. For example, a nut screwed onto a bolt is detachably connected to the bolt. However, two pieces of metal welded together are not considered to be detachably connected to each other. Separating the two pieces of welded metal would damage the weld joint of the two pieces of metal.

The word “controllable” is used in the descriptions of the various embodiments to describe a manner in which a component can perform an action or get to a particular state. For example, a switch may be controllable to connect and disconnect a power supply. In this context, the word “controllable” means that the switch can be controlled to do something—e.g., connect and disconnect a power supply. The control may come from a control signal or control line—wired or wireless—from another component. The phrase “controllable electrical connection” is used in the descriptions of the various embodiments. A “controllable electrical connection” may be controlled—for example, by a controller, a timer, or other logic—to either provide an electrical connection or to be an open circuit.

The above embodiments are for illustrative purposes and are not intended to limit the scope of the disclosure or the adaptation of the features described herein. Those skilled in the art will also appreciate that various adaptations and modifications of the above-described preferred embodiments can be configured without departing from the scope and spirit of the disclosure. Therefore, it is to be understood that, within the scope of the appended claims, the invention may be practiced other than as specifically described.

What is claimed is:

1. A depassivation apparatus for a battery characterized by a battery voltage at a first battery terminal, the apparatus comprising:
a pair of electrodes including a first electrode configured to connect to the first battery terminal of the battery, and second electrode configured to connect to a second battery terminal of the battery;
a voltage monitor and control circuit including a monitor input terminal and a monitor output terminal characterized by a monitor_output_voltage, the monitor input terminal being electrically connected to the first electrode;
a constant current source configured to receive current from the battery and controllably provide a constant current to the monitor output terminal; and
a capacitor electrically connected to the monitor output terminal;
wherein, in response to detecting the monitor_output_voltage to be less than a predetermined recharge threshold voltage, the voltage monitor and control circuit controls the constant current source to turn to an ON state to provide the constant current to the capacitor via the monitor output terminal.

2. The apparatus of claim 1, wherein, in response to detecting the monitor_output_voltage to be equal or greater than a nominal voltage, the voltage monitor and control circuit controls the constant current source to turn to an OFF state, ceasing the constant current to the capacitor.

3. The apparatus of claim 2, wherein, with the constant current source in the OFF state the monitor output terminal is blocked from delivering any current from the battery to a load connected to the monitor output terminal.

4. The apparatus of claim 2, wherein the constant current source is configured as part of the voltage monitor and control circuit, the apparatus further comprising:
an input stabilization circuit including at least one capacitor;
wherein the monitor input terminal is electrically connected to the first electrode via the input stabilization circuit.

5. The apparatus of claim 4, wherein the at least one capacitor includes a first supercapacitor with a capacitor terminal, the apparatus further comprising:
a second supercapacitor electrically connected between the capacitor terminal of the first supercapacitor and the second battery terminal.

6. The apparatus of claim 5, wherein the constant current is 75+/−25 mA, the apparatus further comprising:
capacitor balancing circuitry connected to the capacitor terminal of the first supercapacitor.

7. The apparatus of claim 2, wherein the first electrode and the second electrode are removable electrodes, the apparatus further comprising:
an isolation switch circuit including an isolation input terminal electrically connected to the first battery terminal, and an isolation output terminal.

8. The apparatus of claim 2, wherein the battery is a voltage source to the voltage monitor and control circuit, powering logic circuits within the voltage monitor and control circuit.

9. The apparatus of claim 2, wherein a voltage at the monitor output terminal is less than a voltage at the monitor input terminal by a first value within the range of 150+/−50 mV; and
wherein the predetermined recharge threshold voltage is a second value within the range of 65+/−30 mV.

10. The apparatus of claim 2, wherein the voltage monitor and control circuit is a coulomb counter integrated circuit.

11. A depassivation circuitry apparatus for a battery characterized by a battery voltage at a first battery terminal, the apparatus comprising:
a pair of electrodes including a first electrode configured to connect to the first battery terminal of the battery, and second electrode configured to connect to a second battery terminal of the battery;
a coulomb counter circuit including a monitor input terminal and a monitor output terminal characterized by a monitor_output_voltage, the monitor input terminal being electrically connected to the first electrode of the pair of removable electrodes;
a constant current source configured to receive current from the battery and controllably provide a constant current to the monitor output terminal; and
a capacitor electrically connected to the monitor output terminal;
wherein, in response to detecting the monitor_output_voltage to be less than a predetermined recharge threshold voltage, the coulomb counter circuit controls the constant current source to turn to an ON state to provide the constant current to the capacitor via the monitor output terminal.

12. The apparatus of claim 11, wherein, in response to detecting the monitor_output_voltage to be equal or greater than a nominal voltage, the coulomb counter circuit controls the constant current source to turn to an OFF state, ceasing the constant current to the capacitor.

13. The apparatus of claim 12, wherein, with the constant current source in the OFF state the monitor output terminal is blocked from delivering any current from the battery to a load connected to the monitor output terminal.

14. The apparatus of claim 12, wherein the constant current source is configured as part of the coulomb counter circuit, the apparatus further comprising:
an input stabilization circuit including at least one capacitor;
wherein the monitor input terminal is electrically connected to the first electrode via the input stabilization circuit.

15. The apparatus of claim 14, wherein the at least one capacitor includes a first supercapacitor with a capacitor terminal, the apparatus further comprising:
a second supercapacitor electrically connected between the capacitor terminal of the first supercapacitor and the second battery terminal.

16. The apparatus of claim 15, wherein the constant current is 75+/−25 mA, the apparatus further comprising:
capacitor balancing circuitry connected to the capacitor terminal of the first supercapacitor.

17. The apparatus of claim 12, wherein the first electrode and the second electrode are removable electrodes, the apparatus further comprising:
an isolation switch circuit including an isolation input terminal electrically connected to the first battery terminal, and an isolation output terminal.

18. The apparatus of claim 12, wherein the battery is a voltage source to the coulomb counter circuit, powering logic circuits within the coulomb counter circuit.

19. The apparatus of claim 12, wherein a voltage at the monitor output terminal is less than a voltage at the monitor input terminal by a first value within the range of 150+/−50 mV; and
wherein the predetermined recharge threshold voltage is a second value within the range of 65+/−30 mV.
